(19) United States
(12) Patent Application Publication
(10) Pub. No.: US 2025/0271715 A1
(43) Pub. Date: Aug. 28, 2025

(54) ELECTRO-OPTICAL DEVICE AND ELECTRONIC APPARATUS

(71) Applicant: SEIKO EPSON CORPORATION, Tokyo (JP)

(72) Inventor: Yuki YASHIRO, CHITOSE-SHI (JP)

(73) Assignee: SEIKO EPSON CORPORATION, Tokyo (JP)

(21) Appl. No.: 19/063,345

(22) Filed: Feb. 26, 2025

(30) Foreign Application Priority Data
Feb. 27, 2024 (JP) 2024-027244

(51) Int. Cl. G02F 1/1362; G02F 1/1368

(52) U.S. Cl. CPC G02F 1/136286; G02F 1/1368

(57) ABSTRACT

When data lines are arrayed along an X direction, a transistor P1 of a transmission gate corresponding to the data line in a given column is adjacent, in the X direction, to a transistor N1 of the transmission gate corresponding to the data line adjacent to the data line in the given column, and the transistor N1 of the transmission gate corresponding to the data line in the given column is adjacent, in the X direction, to the transistor P1 of the transmission gate corresponding to the data line adjacent to the data line in the given column.

The present application is based on, and claims priority from JP Application Serial Number 2024-027244, filed Feb. 27, 2024, the disclosure of which is hereby incorporated by reference herein in its entirety.

### BACKGROUND

### 1. Technical Field

The present disclosure relates to an electro-optical device and an electronic apparatus.

### 2. Related Art

In an electro-optical device employing a demultiplexer system, data lines are grouped into sets of a plurality of the data lines, and a data signal supplied to a data signal line provided corresponding to each group is distributed to each of the data lines by a switching element. In such an electro-optical device, in order to improve the writing speed of the data signal with respect to the data line, a technique has been proposed in which switching elements are formed by arranging a P-channel transistor and an N-channel transistor in parallel and complementarily coupling the P-channel transistor and the N-channel transistor to each other (see JP-A-2021-140056).

When the above-described switching elements are arranged in parallel, if the characteristics of the P-channel transistor and the N-channel transistor are not uniform, in particular, if the on-resistances thereof are not uniform, display unevenness may occur. In order to make the characteristics of the transistors uniform, it is conceivable to adjust the transistor sizes of the P-channel transistor and the N-channel transistor.

However, when the transistor sizes are adjusted, a wasteful space is generated in the transistor array, and there is a problem that the array pitch of the data lines cannot be narrowed or the device itself cannot be downsized.

### SUMMARY

In order to solve the problem described above, an electro-optical device according to an aspect of the present disclosure includes data lines grouped into a set of k, k being an integer of two or more, a data signal line to which a data signal is output, the data signal corresponding to a gray scale of a pixel and corresponding to the group of each set of k, and transmission gates provided in a one-to-one correspondence with the data lines. An input end of the transmission gate is coupled to the data signal line, an output end of the transmission gate is coupled to the data line, and a conductive state between the input end and the output end is defined based on a positive logic selection signal and a negative logic selection signal. The transmission gate includes a first transistor of a first conductivity type having a gate node to which the positive logic selection signal is supplied, and a second transistor of a second conductivity type having a gate node to which the negative logic selection signal is supplied. The data lines include a first data line and a second data line adjacent to the first data line in a first direction, and the transmission gates include a first transmission gate provided corresponding to the first data line and a second transmission gate provided corresponding to the second data line. When an array direction of the data lines is the first direction, the first transistor of the first transmission gate is adjacent to the second transistor of the second transmission gate in the first direction, the second transistor of the first transmission gate is adjacent to the first transistor of the second transmission gate in the first direction, and a channel length of the first transistor is different from a channel length of the second transistor.

### BRIEF DESCRIPTION OF THE DRAWINGS

FIG. 1 is a perspective view illustrating an electro-optical device according to an embodiment.

FIG. 2 is a block diagram illustrating a configuration of the electro-optical device.

FIG. 3 is a diagram illustrating a configuration of a pixel circuit in the electro-optical device.

FIG. 4 is a diagram illustrating an arrangement of each component in the electro-optical device.

FIG. 5 is a diagram for describing an operation of the electro-optical device.

FIG. 6 is a diagram illustrating an array of transistors in a transmission gate of an electro-optical device according to a comparative example.

FIG. 7 is a diagram illustrating an equivalent circuit of the array of the transistors.

FIG. 8 is a diagram illustrating an array of the transistors in the transmission gate of the electro-optical device according to the embodiment.

FIG. 9 is a diagram illustrating an array of transistors constituting a NOT circuit of the electro-optical device according to the embodiment.

FIG. 10 is a diagram illustrating a projection-type display device to which the electro-optical device according to the embodiment is applied.

### DESCRIPTION OF EMBODIMENTS

Hereinafter, a projection-type display device according to an embodiment will be described with reference to the drawings. In each of the drawings, dimensions and scales of each portion are made different from actual ones as appropriate. Further, since embodiments to be described below are preferred specific examples, various technically preferable limitations are applied, but the scope of the present disclosure is not limited to the embodiments unless it is otherwise stated in the following description that the present disclosure is limited.

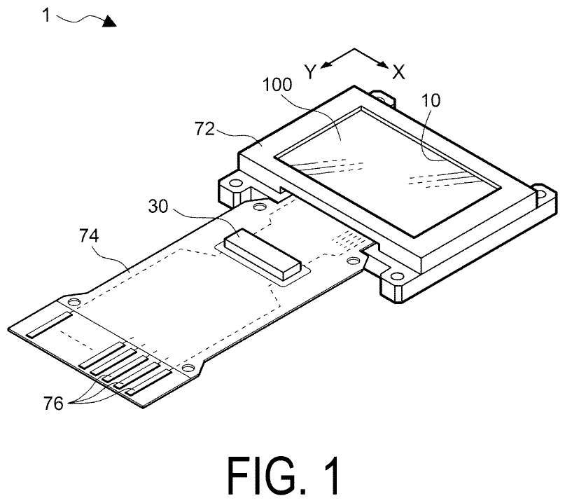

FIG. 1 is a perspective view illustrating a configuration of a module 1 including an electro-optical device 100 according to an embodiment.

The electro-optical device 100 is, for example, a transmissive-type liquid crystal panel used as a light valve of a projection-type display device. The electro-optical device 100 is accommodated in a frame-shaped case 72 that opens at a rectangular display region 10. One end of an FPC substrate 74 is coupled to the electro-optical device 100. Note that FPC is an abbreviation for flexible printed circuits. A plurality of terminals 76 are provided at the other end of the FPC substrate 74 and coupled to an upper circuit (not illustrated).

A display control circuit 30 constituted by a semiconductor chip is mounted on the FPC substrate 74 by face-down bonding, and video data are supplied to the FPC substrate 74 from the upper circuit via the plurality of terminals 76 in synchronization with a synchronization signal. The video data defines a gray scale of a pixel in an image to be displayed, for example, by 8 bits.

Note that, in the drawings, an X direction is a longitudinal direction of the display region 10 and is a direction in which scanning lines extend, and a Y direction is a lateral direction of the display region 10 and is a direction in which data lines extend.

When the electro-optical device 100 is used as a light valve of a projection-type display device, as will be described later, transmitted images generated by three of the electro-optical devices 100 respectively corresponding to primary colors R (red), G (green), and B (blue) are combined to express a color image.

Therefore, a pixel which is a minimum unit of the color image is expressed by additive color mixing, using a red sub-pixel by the electro-optical device 100 corresponding to R, a green sub-pixel by the electro-optical device 100 corresponding to G, and a blue sub-pixel by the electro-optical device 100 corresponding to B. However, with regard to the red, green, and blue sub-pixels, when there is no need to specify the colors, or when dealing with only the brightness as a problem, the sub-pixels need not necessarily be referred to as sub-pixels. Thus, in this description, the red, green, and blue sub-pixels will be simply referred to as “pixels”.

The synchronization signal includes a vertical synchronization signal for transmitting an instruction to the pixels arrayed in the display region 10 to start vertical scanning, a horizontal synchronization signal for transmitting an instruction to the pixels to start horizontal scanning, and a clock signal indicating a timing for one pixel of the video data. The display control circuit 30 processes the video data and the synchronization signal, and outputs a data signal and a control signal necessary for driving the electro-optical device 100. The data signal is a signal obtained by converting the video data into an analog signal, and the control signal is a signal for controlling the vertical scanning and the horizontal scanning in the electro-optical device 100.

Note that the display control circuit 30 need not necessarily be mounted on the FPC substrate 74, but may be provided in the upper circuit and configured so that a video signal and the control signal are supplied via the terminals 76.

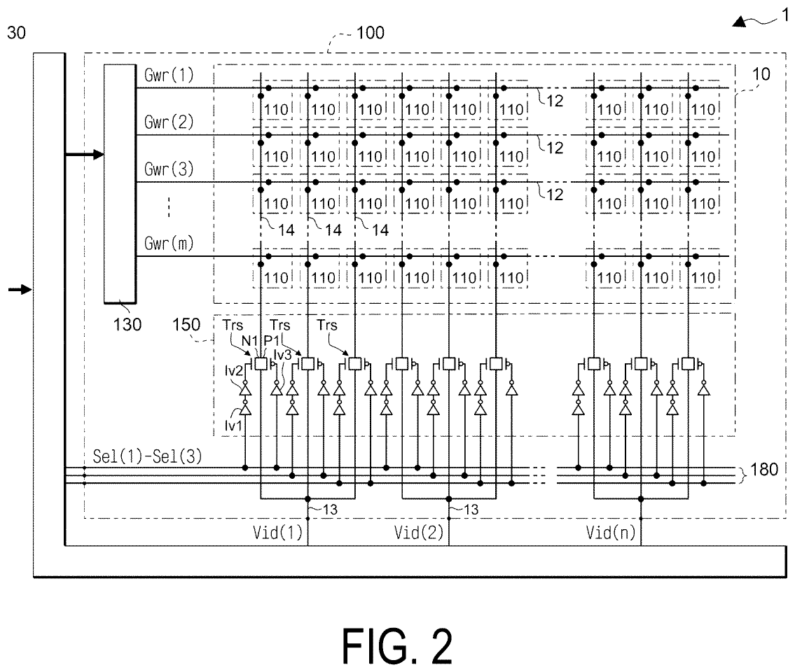

FIG. 2 is a block diagram illustrating an electrical configuration of the module 1. The module 1 includes the above-described electro-optical device 100 and display control circuit 30. A scanning line drive circuit 130 and a peripheral circuit 150 are provided at the periphery of the display region 10 of the electro-optical device 100.

The electro-optical device 100 has a configuration in which liquid crystal is sealed by an element substrate at which thin film transistors and the like are formed and a counter substrate at which a common electrode is formed, and the scanning line drive circuit 130 and the peripheral circuit 150 are formed at the element substrate.

In the display region 10 of the electro-optical device 100, pixel circuits 110 corresponding to pixels of an image to be displayed are arrayed in a matrix. More specifically, in the display region 10, m rows of scanning lines 12 are provided to extend in a horizontal direction in the drawing, and (3n) columns of data lines 14 grouped into sets of three columns are provided to extend in a vertical direction in the drawing and to be electrically insulated from the scanning lines 12. The pixel circuits 110 are provided to correspond to intersections between the m rows of scanning lines 12 and the (3n) columns of data lines 14. Therefore, in this embodiment, the pixel circuits 110 are arrayed in a matrix pattern including m rows vertically and (3n) columns horizontally.

Here, “m” is an integer of 2 or more. n is an integer of 2 or more, and n is set to 3 in this embodiment.

An integer i of one or more and m or less is used to generalize and describe the rows of the scanning lines 12 and the rows in the matrix array of the pixel circuits 110. For example, with respect to the scanning lines 12, the rows may be referred to as the first, second, third, . . . , (i−1)-th, i-th, . . . , (m−1)-th, and m-th rows in order from the top in the drawing.

Similarly, an integer j of one or more and n or less is used to generalize and describe the columns of the data lines 14 and the columns in the matrix array of the pixel circuits 110. For example, in order to distinguish the data lines 14, the columns may be referred to as the first, second, third, . . . , (3j−2)-th, (3j−1)-th, (3j)-th, . . . , (3n−2)-th, (3n−1)-th, and (3n)-th columns in order from the left in the drawing.

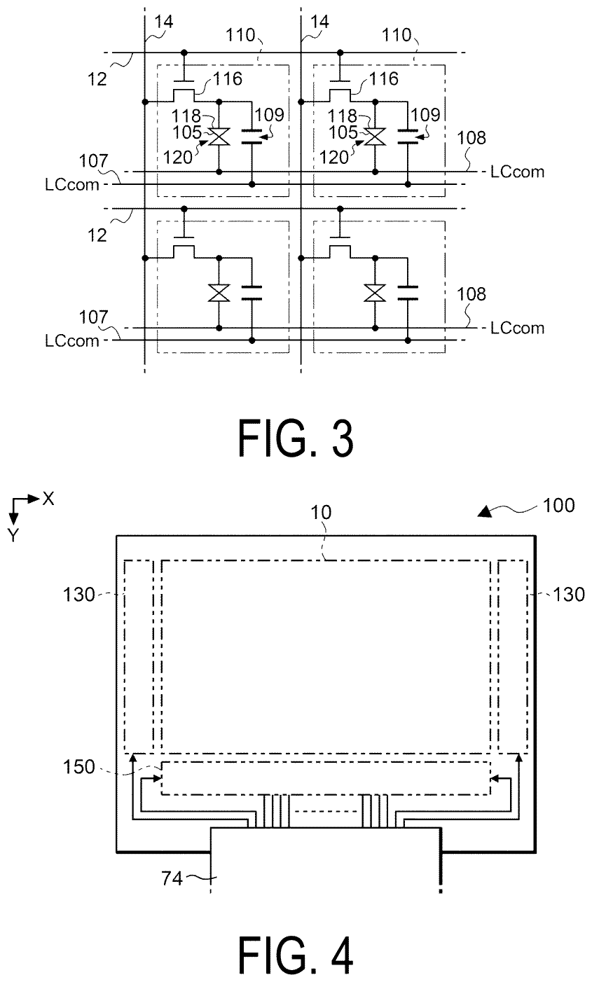

For convenience of description, a configuration of the pixel circuit 110 will be described with reference to FIG. 3.

FIG. 3 is a diagram illustrating an equivalent circuit of a total of four of the pixel circuits 110, in two rows and two columns, corresponding to the intersections between two of the scanning lines 12 adjacent to each other and two of the data lines 14 adjacent to each other.

As illustrated in FIG. 3, the pixel circuit 110 includes a transistor 116 and a liquid crystal element 120. The transistor 116 is, for example, an N-channel thin film transistor. In the pixel circuit 110, the transistor 116 has a gate node coupled to the scanning line 12, a source node coupled to the data line 14, and a drain node coupled to a pixel electrode 118.

In this description, “coupled” means direct or indirect connection or coupling between two or more elements, and includes, for example, coupling between two or more elements via different wiring layers and contact holes even when the two or more elements are not directly coupled in a semiconductor substrate.

A common electrode 108 is provided at the counter substrate in common to all the pixels to face the pixel electrode 118. The common electrode 108 is maintained at a potential LCcom that is substantially constant over time. Then, a liquid crystal 105 is interposed between the pixel electrodes 118 and the common electrode 108. Therefore, in each of the pixel circuits 110, the liquid crystal element 120 is constituted by the pixel electrode 118, the common electrode 108, and the liquid crystal 105.

Further, a storage capacitor 109 is provided electrically in parallel with the liquid crystal element 120. The storage capacitor 109 has one end coupled to the pixel electrode 118 and the other end coupled to a capacitance line 107. The capacitance line 107 is maintained at a potential that is constant over time, such as the potential LCcom that is the same as the potential applied to the common electrode 108.

Returning to FIG. 2 once again, in this embodiment, (3n) columns of the data lines 14 grouped into sets of three columns. Three of the data lines 14, that is, the data lines 14 of the (3j−2)-th, (3j−1)-th, and (3j)-th columns, correspond to a j-th group when counted from the left in the drawing.

Further, with respect to the data lines 14, in the case of the j-th group, description may be made while regarding the (3j−2)-th column as a first sequence, the (3j−1)-th column as a second sequence, and the (3j)-th column as a third sequence. In other words, in the j-th group, the data line 14 of the first sequence is the (3j−2)-th column, the data line 14 of the second sequence is the (3j−1)-th column, and the data line 14 of the third sequence is the (3j)-th column.

The display control circuit 30 processes the video data and the synchronization signal supplied from the upper circuit, and outputs data signals Vid(1), Vid(2), Vid(3), . . . , and Vid(n) and selection signals Sel(1) to Sel(3) in addition to the control signal to the scanning line drive circuit 130.

The data signals Vid(1), Vid(2), Vid 3), . . . , and Vid(n) are supplied to the electro-optical device 100 via n data signal lines 13.

The data signals Vid(1), Vid(2), Vid(3), . . . , and Vid(n) will be generalized and described. A data signal Vid(j) is a signal for supplying, in a time-division manner during a horizontal scanning period, potentials respectively corresponding to gray scales of three pixels corresponding to the intersections between the three data lines 14 belonging to the j-th group and the scanning line 12 to be horizontally scanned.

The selection signal Sel(1) is a signal for selecting the data line 14 of the first sequence. Similarly, the selection signal Sel(2) is a signal for selecting the data line 14 of the second sequence, and the selection signal Sel(3) is a signal for selecting the data line 14 of the third sequence.

The scanning line drive circuit 130 supplies scanning signals individually to m rows of the scanning lines 12 under the control of the display control circuit 30. Here, the scanning signal supplied to the scanning line 12 of the first row is denoted by Gwr(1), and thereafter, similarly, the scanning signals supplied to the scanning lines 12 of the second, third, . . . , (i−1)-th, i-th, . . . , (m−1)-th, and the m-th rows are denoted by Gwr(2), Gwr(3), Gwr(i−1), Gwr(i), . . . , Gwr(m−1), and Gwr(m), respectively.

The display control circuit 30 outputs various control signals for controlling the scanning line drive circuit 130. However, since the control signals to the scanning line drive circuit 130 are not important in this description, only signal paths are illustrated and a detailed description of the control signals is omitted.

The peripheral circuit 150 is a circuit that distributes the data signals to the data lines 14 in accordance with the selection signals Sel(1) to Sel(3). More specifically, the peripheral circuit 150 includes a transmission gate Trs and NOT circuits Iv1, Iv2, and Iv3 for each column of the data lines 14.

The transmission gate Trs is an analog switch in which a P-channel transistor P1 and an N-channel transistor N1 are coupled to each other in parallel. The transistors P1 and N1 are thin film transistors similar to the transistor 116 in the pixel circuit 110.

In the transmission gate Trs corresponding to the data line 14 of the first sequence in the j-th group, the input end is coupled to the data signal line 13 corresponding to the j-th group, and the output end is coupled to the data line 14 of the first sequence in the j-th group.

In the transmission gate Trs corresponding to the data line 14 of the second sequence in the j-th group, the input end is coupled to the data signal line 13 corresponding to the j-th group, and the output end is coupled to the data line 14 of the second sequence in the j-th group. Similarly, in the transmission gate Trs corresponding to the data line 14 of the third sequence in the j-th group, the input end is coupled to the data signal line 13 corresponding to the j-th group, and the output end is coupled to the data line 14 of the third sequence in the j-th group.

In other words, the input ends of the transmission gates Trs corresponding to the three data lines 14 belonging to the j-th group are commonly coupled to the data signal line 13 corresponding to the j-th group. The output end of the transmission gate Trs is coupled to the corresponding data line 14.

In the j-th group, of the NOT circuits Iv1 and Iv2 corresponding to the data line 14 of the first sequence, the NOT circuit Iv1 inverts the logic level of the selection signal Sel(1) and outputs the inverted signal, and the NOT circuit Iv2 re-inverts the logic level of the inverted signal from the NOT circuit Iv1 and outputs the re-inverted signal. That is, the two NOT circuits Iv1 and Iv2 corresponding to the data line 14 of the first sequence are buffer circuits that buffer the logic level of the selection signal Sel(1). Note that, in the j-th group, the NOT circuit Iv2 corresponding to the data line 14 of the first sequence supplies the buffered selection signal Sel(1) to the gate node of the transistor N1 in the transmission gate Trs of the first sequence.

In the j-th group, the NOT circuit Iv3 corresponding to the data line 14 of the first sequence inverts the logic level of the selection signal Sel(1) and supplies the inverted signal to the gate node of the transistor P1 in the transmission gate Trs of the first sequence.

In the j-th group, similarly, the NOT circuits Iv1 and Iv2 corresponding to the data line 14 of the second sequence buffer the selection signal Sel(2) and supply the buffered selection signal Sel(2) to the gate node of the transistor N1 in the transmission gate Trs of the second sequence. In the j-th group, similarly, the NOT circuit Iv3 corresponding to the data line 14 of the second sequence inverts the logic level of the selection signal Sel(2) and supplies the inverted signal to the gate node of the transistor P1 in the transmission gate Trs of the second sequence.

In the j-th group, similarly, the NOT circuits Iv1 and Iv2 corresponding to the data line 14 of the third sequence buffer the selection signal Sel(3) and supply the buffered selection signal Sel(3) to the gate node of the transistor N1 in the transmission gate Trs of the third sequence. In the j-th group, similarly, the NOT circuit Iv3 corresponding to the data line 14 of the third sequence inverts the logic level of the selection signal Sel(3) and supplies the inverted signal to the gate node of the transistor P1 in the transmission gate Trs of the third sequence.

Note that FIG. 2 is a diagram for illustrating an electrical configuration of the electro-optical device 100, and each element in the electro-optical device 100 is actually arranged as illustrated in FIG. 4.

When m<3n, the display region 10 has a rectangular shape in which the X direction is longer than the Y direction.

As described above, one end of the FPC substrate 194 is coupled to one longitudinal side of the electro-optical device 100. The peripheral circuit 150 is provided between the one end of the FPC substrate 74 and the display region 10.

The scanning line drive circuit 130 is provided outside each of two sides along the Y direction of the display region 10. Specifically, there is adopted a configuration in which two of the scanning line drive circuits 130 are provided and the scanning signal is supplied from both the ends of the scanning line 12. The reason for adopting such a configuration is that it is possible to suppress an influence on the display caused by a delay in the scanning signal, compared to a case in which the scanning signal is supplied from only one end.

Note that the same control signal is supplied from the display control circuit 30 to the two scanning line drive circuits 130. Further, although the selection signals Sel(1) to Sel(3) are supplied from one end in FIG. 2, similarly to the scanning signals, as illustrated in FIG. 4, the selection signals Sel(1) to Sel(3) are supplied from both the left and right ends in order to suppress the influence of the delay.

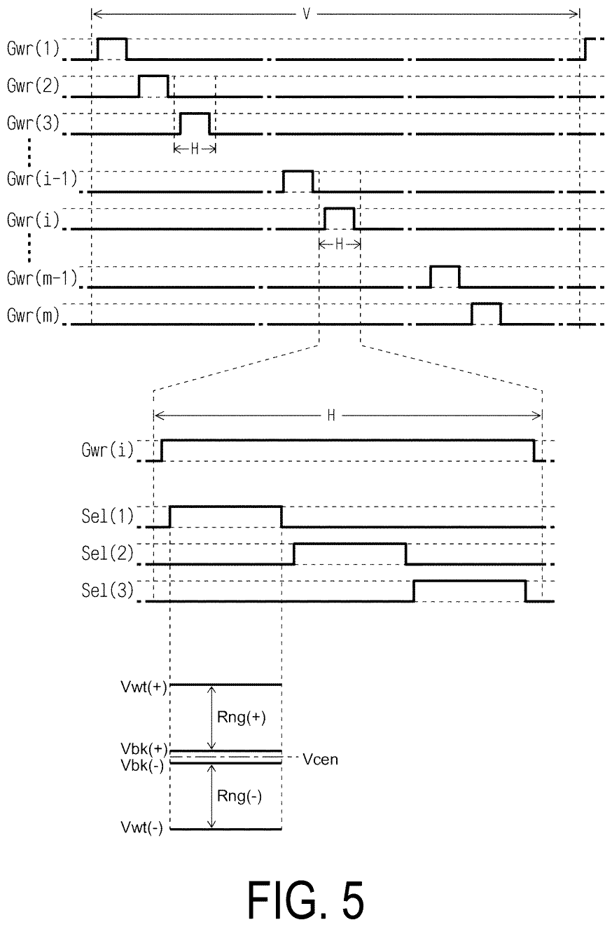

FIG. 5 is a timing chart illustrating an operation of the electro-optical device 100.

In the electro-optical device 100, m rows of the scanning lines 12 are scanned one by one in the order of first, second, third, . . . , and m-th rows during a period of a frame (V). More specifically, as illustrated in FIG. 5, the scanning signals Gwr(1), Gwr(2), . . . , Gwr(i−1), Gwr(i), . . . , Gwr(m−1), and Gwr(m) sequentially and exclusively reach a H level for each horizontal scanning period (H) by the scanning line drive circuit 130.

Note that, in this embodiment, a period in which the adjacent scanning signals among the scanning signals Gwr(1) to Gwr(m) reach the H level is temporally isolated. Specifically, after the scanning signal Gwr(i−1) changes from the H level to an L level, the next scanning signal Gwr(i) reaches the H level after a period of time. This period corresponds to a horizontal return period.

In this description, the period of one frame (V) refers to a period required to display one frame of an image designated by the video data supplied from the upper circuit. When a length of the period of one frame (V) is the same as a vertical synchronization period, for example, when a frequency of the vertical synchronization signal included in a synchronization signal Sync is 60 Hz, it is 16.7 milliseconds, which corresponds to one cycle of the vertical synchronization signal. Further, the horizontal scanning period (H) is an interval of time in which the scanning signals Gwr(1) to Gwr(m) reach the H level in order, but in the drawing, for convenience, a start timing of the horizontal scanning period (H) is approximately the center of the horizontal return period.

When a given scanning signal among the scanning signals Gwr(1) to Gwr(m), for example, the scanning signal Gwr(i) supplied to the scanning line 12 in the i-th row reaches the H level, the transistor 116 in the pixel circuit 110 located in the i-th row obtains a ON state. Therefore, in the pixel circuit 110, a state is obtained in which one end of the liquid crystal element 120 and one end of the storage capacitor 109 are electrically coupled to the corresponding data line 14. In the case of the pixel circuit 110 in the i-th row and the (3j−2)-th column, one end of the liquid crystal element 120 and one end of the storage capacitor 109 in the pixel circuit 110 are electrically coupled to the data line 14 in the (3j−2)-th column.

Note that, in this description, the “ON state” of the transistor means that a space between the source node and the drain node in the transistor is electrically closed to be in a low impedance state. Further, an “OFF state” of the transistor means that the space between the source node and the drain node is electrically opened to be in a high impedance state.

In a period in which the scanning signal Gwr(i) is at the H level, the selection signals Sel(1), Sel(2), and Sel(3) sequentially and exclusively reach the H level.

When the selection signal Sel(1) reaches the H level, in the first sequence, the output of the NOT circuit Iv2 reaches the H level, and the output of the NOT circuit Iv3 reaches the L level. Therefore, the transmission gate Trs of the first sequence obtains the ON state.

The display control circuit 30 sequentially outputs the potentials of the data signals Vid(1), Vid(2), . . . , Vid(j), . . . , and Vid(n) at the potentials corresponding to the gray scales of the pixels in the i-th row and the first, fourth, . . . , (3j-2), . . . , and (3n−2) columns and also corresponding to the writing polarities.

Thus, the data signal Vid(j) is applied to one end of the liquid crystal element 120 and one end of the storage capacitor 109 in the pixel circuit 110 in the i-th row and the (3j−2)-th column, via the data line 14 in the (3j−2)-th column. The potential of the signal Vid(j) applied to the one end of the liquid crystal element 120 is held by the capacitance of the liquid crystal element 120 and the storage capacitor 109 even when the transmission gate Trs in the (3j−2)-th column obtains the OFF state, and further, even when the horizontal scanning period of the i-th row ends and the scanning signal Gwr(i) reaches the L level.

As is well known, in the liquid crystal element 120, the orientation of liquid crystal molecules changes depending on an electric field generated by the pixel electrode 118 and the common electrode 108. Therefore, the liquid crystal element 120 has a transmittance according to an effective value of an applied voltage.

Note that, in this embodiment, it is assumed that a normally black mode is employed in which the transmittance is lowest when the voltage applied to the liquid crystal element 120 is zero and the transmittance increases as the voltage applied to the liquid crystal element 120 increases.

The data signal Vid(j) is a potential corresponding to the gray scale of the pixel in the i-th row and the (3j−2)-th column, and is a potential corresponding to the writing polarity. When the liquid crystal element 120 is driven, it is necessary to perform AC driving in order to prevent deterioration of the liquid crystal 105. Thus, when the liquid crystal element 120 is driven, a high-level positive polarity potential and a low-level negative polarity potential relative to a potential Vcen at the center of the amplitude are applied to the pixel electrode 118 in an alternating manner, for example, for every period of the one frame (V). Note that the potential Vcen may be regarded as substantially the same potential as the potential LCcom to be applied to the common electrode 108.

The positive polarity potential can take a potential within a range Rng(+). The range Rng(+) is, for example, from a potential Vwt(+) obtained when the gray scale is the highest value to a potential Vbk(+) obtained when the gray scale is the lowest value. The negative polarity potential can take a potential within a range Rng(−). The range Rng(−) is, for example, from a potential Vwt(−) obtained when the gray scale is the highest value to a potential Vbk(−) obtained when the gray scale is the lowest value.

Here, of the horizontal scanning of the i-th row, description has been made on the (3j−2)-th column. However, the same operation is performed for the first, fourth, seventh, . . . and (3n−2)-th columns of the first sequence in the same manner. The selection signal Sel(1) reaches the L level, and then the selection signal Sel(2) reaches the H level.

When the selection signal Sel(2) reaches the H level, the transmission gate Trs of the second sequence obtains the ON state. The display control circuit 30 sequentially outputs the potentials of the signals Vid(1), Vid(2), . . . , Vid(j), . . . , and Vid(n) corresponding to the gray scales of the pixels in the i-th row and the second, fifth, . . . , (3j−1)-th, . . . , and (3n−1)-th columns and also corresponding to the writing polarities. Accordingly, the liquid crystal element 120 of the pixel circuit 110 corresponding to the intersection of the scanning line of the i-th row and the data line 14 of the second sequence has the transmittance corresponding to the gray scale.

The selection signal Sel(2) reaches the L level, and then the selection signal Sel(3) reaches the H level.

When the selection signal Sel(3) reaches the H level, the transmission gate Trs of the third sequence obtains the ON state. The display control circuit 30 sequentially outputs the potentials of the signals Vid(1), Vid(2), . . . , Vid(j), . . . , and Vid(n) corresponding pt the gray scales of the pixels in the i-th row and the third, sixth, . . . , (3j)-th, . . . , and (3n)-th columns and also corresponding to the writing polarities. Accordingly, the liquid crystal element 120 of the pixel circuit 110 corresponding to the intersection of the scanning line of the i-th row and the data line 14 of the third sequence has the transmittance corresponding to the gray scale. Thereafter, the selection signal Sel(3) reaches the L level, and the horizontal scanning of the i-th row ends.

Here, description has been made on the horizontal scanning of the i-th row. However, the same operation is performed sequentially for the first, second, third, . . . , and m-th rows.

When the horizontal scanning of the m-th row ends, the operation transitions to a period of the next frame, and the horizontal scanning is started once again from the first row. Note that, in the period of the next frame, the display control circuit 30 inverts the potential polarity of the data signal.

Even in a configuration in which the transmission gate Trs is replaced with only one of the transistors P1 and N1, it is possible to write, namely, transmit the data signal supplied to the data signal line 13 to the data line 14.

However, in such a configuration, for example, with only the transistor N1, the resistance value in the ON state becomes high, and the data signal supplied to the data signal line 13 cannot be sufficiently written to the data line 14 from the viewpoint of the time constant.

Further, in the transistor P1 or N1, when the potential difference between the gate node and the source node is small, the data signal supplied to the data signal line 13 is less likely to be written to the data line 14 as compared to a case in which the potential difference is large.

Specifically, in the case of the transistor N1, the potential difference between the gate node and the source node becomes smaller the closer the data signal is to the positive polarity potential of the high gray scale, that is, to the potential Vwt(+). Thus, the writing of the data signal to the data line 14 becomes insufficient. On the contrary, in the case of the transistor P1, the closer the data signal is to the negative polarity potential of the high gray scale, that is, to the potential Vwt(−), the more insufficient the writing of the data signal to the data line 14 becomes.

In a configuration in which only one of the transistors P1 and N1 is used as an element for writing the data signal supplied to the data signal line 13 to the data line 14, there is a problem that not only the writing becomes insufficient but also display unevenness occurs due to the difference in polarity.

Such a problem becomes notable when the data signal is distributed to a large number of the data lines 14 within a limited period of time, that is, when intending to perform display at a high resolution.

Therefore, in this embodiment, as described above, the element for writing the data signal supplied to the data signal line 13 to the data line 14 is constituted by the transmission gate Trs in which the transistors P1 and N1 are complementarily coupled to each other in parallel.

In the transmission gate Trs, since the transistors P1 and N1 simultaneously obtain the ON state, the on-resistance is substantially halved as compared to a configuration in which only one of the transistors is provided. Further, in the transmission gate Trs, the transistor P1 compensates for insufficient writing by the transistor N1 at the positive polarity potential of the high gray scale. On the contrary, the transistor N1 compensates for insufficient writing by the transistor P1 at the negative polarity potential of the high gray scale. Therefore, when the transmission gate Trs is used, the display unevenness arising from the difference in polarity is also suppressed.

In this way, in order to perform display at a high resolution, it is preferable that the switching element for writing the data signal supplied to the data signal line 13 to the data line 14 is constituted by the transmission gate Trs.

Next, a problem arising from the above-described configuration in which the switching element is constituted by the transmission gate Trs will be examined.

It is desirable that the transistors P1 and N1 constituting the transmission gate Trs have the same characteristics, particularly the same on-resistance. It is known that when the transistors P1 and N1 are designed according to the same design rule, specifically, when the channel lengths and the channel widths are designed to have the same values, it is difficult to match the characteristics of the transistors P1 and N1 only by adjusting the process conditions.

Thus, it has been considered to adjust the transistor sizes of the transistors P1 and N1. Specifically, for example, if the characteristics of the transistor P1 are inferior to the characteristics of the transistor N1, it is conceivable to design the channel length of the transistor P1 to be shorter than the channel length of the transistor P1.

Next, in such a design, a case in which the transistors P1 and N1 are arrayed corresponding to the data lines 14 will be examined. The transistors P1 and N1 need to be provided in a one-to-one correspondence with the data lines 14.

Further, since an extending direction of the data signal line 13 and the data line 14 is the Y direction, in the transistors P1 and N1, the gate node, the source node, the drain node, and wiring coupled thereto may also be configured to extend in the Y direction.

Therefore, a configuration is conceivable in which the transistors P1 and N1 constituting the transmission gate Trs in a given column are arrayed as follows.

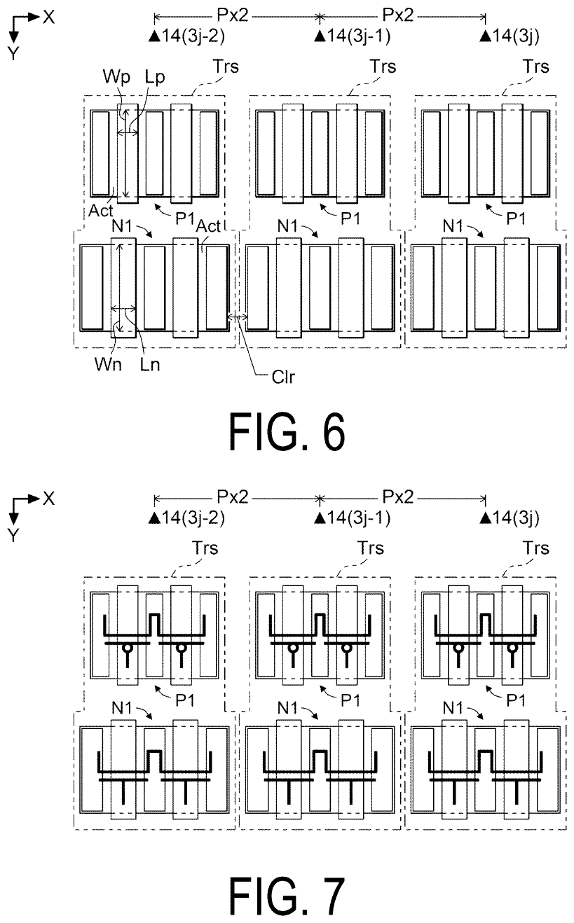

FIG. 6 is a plan view illustrating an array of the transistors P1 and N1 of the transmission gate Trs in an electro-optical device according to a comparative example.

In the comparative example, the transistors P1 and N1 constituting the transmission gate Trs are arrayed along the Y direction, which is the extending direction of the data signal line 13 and the data line 14, and the transmission gates Trs are arrayed along the X direction.

Note that, in the comparative example, the transistor P1 has a configuration in which two P-channel transistors are arrayed in parallel. More specifically, as illustrated in FIG. 7, two P-channel transistors in which one of the source node and the drain node is shared and the other of the source node and the drain node is independent are arrayed in parallel. Similarly, the transistor N1 has a configuration in which two N-channel transistors are arrayed in parallel.

Note that, in FIGS. 6 and 7, in order to illustrate the array of the transistors P1 and N1 in an easily understandable manner, semiconductor layers Act of the transistors P1 and N1 each have an independent island shape, but the semiconductor layer Act may be configured to extend in the X direction or may be configured to be solidly formed over the surface.

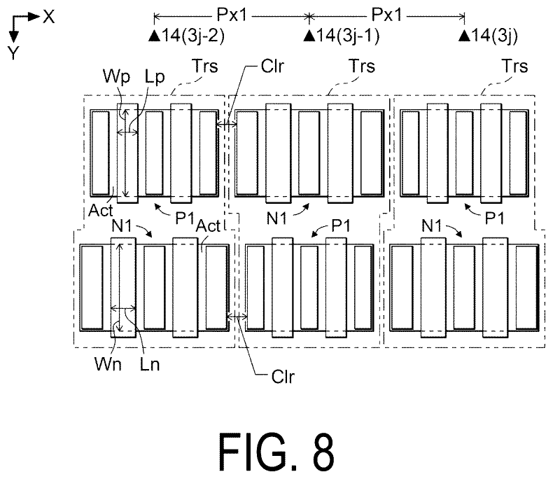

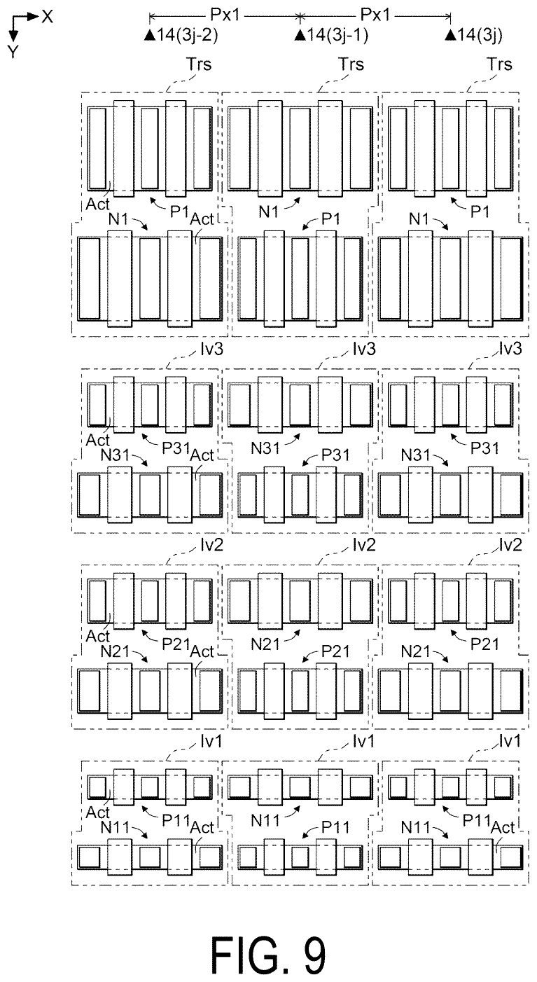

In FIGS. 6 and 7, and further in FIGS. 8 and 9 to be described later, in order to describe the array of the transistors in an easily understandable manner, the wiring and the like coupled to the gate, source, and drain nodes are omitted.

If the characteristics of the transistor P1 are inferior to the characteristics of the transistor N1, as described above, the transistor sizes are designed such that a channel length Lp of the transistor P1 is shorter than a channel length Ln of the transistor N1.

In such a design, a case will be examined in which the transistors P1 and N1 of one transmission gate Trs are arrayed along the Y direction, and the transmission gates Trs are provided in a one-to-one correspondence with the data lines 14 along the X direction.

In this case, since it is necessary to secure a clearance Clr, which is defined by the design rule, between the transistors N1 adjacent to each other in the X direction, a pitch Px2 of the data lines 14 is defined by the channel length Ln of the transistor N1.

That is, in the array as illustrated in FIG. 7, the pitch Px2 of the data lines 14 is defined by the channel length Ln of the transistor N1, and thus as a disadvantage, it is not possible to respond to needs of narrowing of the pitch or downsizing. On the other hand, the transistors P1 adjacent to each other in the X direction are arrayed at an interval larger than the clearance Clr, and in this sense, it can be said that a wasteful space is generated.

Note that, in FIG. 7, a channel width Wp of the transistor P1 and a channel width Wn of the transistor N1 are equal to each other. The channel widths Wp and Wn do not affect the pitch Px2 of the data lines 14.

In order to resolve the above-described disadvantage, in this embodiment, the transistors P1 and N1 are arrayed as follows.

FIG. 8 is a diagram illustrating an array of the transistors P1 and N1 constituting the transmission gate Trs in the electro-optical device 100 according to the embodiment.

The embodiment is similar to the comparative example illustrated in FIG. 6 in that the transistors P1 and N1 of the transmission gate Trs in a given column are arrayed along the Y direction. However, in this embodiment, the transistor P1 of the transmission gate Trs corresponding to the data line 14 in a given column is adjacent to the transistor N1 of the transmission gate Trs corresponding to the data line 14 adjacent to the data line 14 in the given column in the X direction. Further, the transistor N1 of the transmission gate Trs corresponding to the data line 14 in the given column is adjacent to the transistor P1 of the transmission gate Trs corresponding to the data line 14 adjacent to the data line 14 in the given column in the X direction.

In other words, if the transistors P1 and N1 are arrayed in this order along the Y direction in the transmission gate Trs corresponding to the data line 14 in a given column, conversely, in the transmission gate Trs corresponding to the data line 14 adjacent to the data line 14 in the given column in the X direction, the transistors N1 and P1 are arrayed in this order along the Y direction.

Thus, in this embodiment, both the clearance between one transistor P1 and the transistor N1 adjacent to the one transistor P1 in the X direction and the clearance between one transistor N1 and the transistor P1 adjacent to the one transistor N1 in the X direction can be set to the clearance Clr having the same value.

Therefore, a pitch Px1 of the data lines 14 in this embodiment can be made narrower than the pitch Px2 in the comparative example. Thus, it is possible to more easily respond to the needs of the narrowing of the pitch or downsizing compared to the comparative example.

For example, even if the pitch Px1 of the data lines 14 in this embodiment is smaller than the pitch Px2 of the data lines 14 in the comparative example by as small as about 0.2 μm, if the number of data lines 14 is 1920, the length of the display region 10 in the X direction can be made shorter than that in the comparative example by about 0.38 mm, and this difference is large in a microdisplay.

In FIG. 8, the array of the transistors P1 and N1 constituting the transmission gate Trs has been described. The above-described array can be applied not only to the transistors P1 and N1 constituting the transmission gate Trs, but also to P-channel transistors and N-channel transistors constituting the NOT circuits Iv1, Iv2, and Iv3.

FIG. 9 is a plan view illustrating an example of an array of the P-channel transistors and the N-channel transistors constituting the NOT circuits Iv1, Iv2, and Iv3, respectively. In this example, the NOT circuits Iv3, Iv2, and Iv1 are arrayed in the Y direction in this order starting from the transmission gate Trs.

As is well known, an inverter such as the NOT circuit Iv1 has a configuration in which a P-channel transistor P11 and an N-channel transistor N11 are coupled in series between power supply voltages. Similarly, the NOT circuit Iv2 has a configuration in which a P-channel transistor P21 and an N-channel transistor N21 are coupled in series between the power supply voltages. Similarly, the NOT circuit Iv3 has a configuration in which a P-channel transistor P31 and an N-channel transistor N31 are coupled in series between the power supply voltages.

The transistor P11 of the NOT circuit Iv1 corresponding to the data line 14 in a given column is adjacent to the transistor N11 of the NOT circuit Iv1 corresponding to the data line 14 adjacent to the data line 14 in the given column in the X direction. Further, the transistor N11 of the NOT circuit Iv1 corresponding to the data line 14 in the given column is adjacent to the transistor P11 of the NOT circuit Iv1 corresponding to the data line 14 adjacent to the data line 14 in the given column in the X direction.

Similarly, the transistor P21 of the NOT circuit Iv2 corresponding to the data line 14 in a given column is adjacent to the transistor N21 of the NOT circuit Iv2 corresponding to the data line 14 adjacent to the data line 14 in the given column in the X direction. Further, the transistor N21 of the NOT circuit Iv2 corresponding to the data line 14 in the given column is adjacent to the transistor P21 of the NOT circuit Iv2 corresponding to the data line 14 adjacent to the data line 14 in the given column in the X direction.

Similarly, the transistor P31 of the NOT circuit Iv3 corresponding to the data line 14 in a given column is adjacent to the transistor N31 of the NOT circuit Iv3 corresponding to the data line 14 adjacent to the data line 14 in the given column in the X direction. Further, the transistor N31 of the NOT circuit Iv3 corresponding to the data line 14 in the given column is adjacent to the transistor P31 of the NOT circuit Iv3 corresponding to the data line 14 adjacent to the data line 14 in the given column in the X direction.

The reason why the channel widths of the transistors P11 and N11 in the NOT circuit Iv1 are narrower than the channel widths of the transistors P21 and N21 in the NOT circuit Iv2 is as follows. More specifically, this is because the NOT circuit Iv2 is a main amplifier that amplifies and supplies one of the selection signals Sel(1) to Sel(3) to the gate node of the transistor N1, whereas the NOT circuit Iv1 is a preamplifier that is a previous stage of the NOT circuit Iv2. The NOT circuit Iv3 serves as a main amplifier that amplifies and supplies an inverted signal of one of the selection signals Sel(1) to Sel(3) to the gate node of the transistor P1. Therefore, the channel widths of the transistors P31 and N31 in the NOT circuit Iv3 are substantially the same as the channel widths of the transistors P11 and N11 in the NOT circuit Iv1, which also serves as a main amplifier.

The channel lengths of the transistors P11, P21, and P31 are equal to the channel length Lp of the transistor P1, and the channel lengths of the transistors N11, N21, and N31 are equal to the channel length Ln of the transistor N1.

In this way, according to the NOT circuits Iv1, Iv2 and Iv3, they can be arrayed at the pitch Px1 of the data lines 14 in the same manner as with the transmission gates Trs.

Note that if the drive capability of the display control circuit 30 is high, of the NOT circuits Iv1, Iv2, and Iv3, the NOT circuits Iv1 and Iv2 that buffer the selection signals Sel(1) to Sel(3) need not necessarily be provided. In other words, by providing the NOT circuits Iv1 and Iv2, a high drive capability is not required in the display control circuit 30.

Further, if the display control circuit 30 supplies each of the inverted signals of the selection signals Sel(1) to Sel(3), the NOT circuit Iv3 is not required.

The P-channel is an example of a “first conductivity type”, the transistor P1 is an example of a “first transistor”, the N-channel is an example of a “second conductivity type”, and the transistor N1 is an example of a “second transistor”.

The data line 14 in the (3j−2)-th column is an example of a “first data line”, and the data line 14 in the (3j−1)-th column is an example of a “second data line”. The transmission gate Trs in the (3j−2)-th column is an example of a “first transmission gate”, and the transmission gate Trs in the (3j−1)-th column is an example of a “second transmission gate”. The X direction is an example of a “first direction”, and the Y direction is an example of a “second direction”. The NOT circuit Iv2 is an example of a “first NOT circuit”, the transistor P21 is an example of a “third transistor”, and the transistor N21 is an example of a “fourth transistor”. The NOT circuit Iv3 is an example of a “second NOT circuit”, the transistor P31 is an example of a “fifth transistor”, and the transistor N31 is an example of a “sixth transistor”.

In the embodiment, in the transmission gate Trs, the channel length Lp of the transistor P1 is set to be shorter than the channel length Ln of the transistor N1 assuming that the characteristics of the transistor P1 are inferior to the characteristics of the transistor N1. If the characteristics of the transistor N1 are inferior to the characteristics of the transistor P1, the channel length Ln of the transistor N1 may be made shorter than the channel length Lp of the transistor P1.

In the embodiment, description has been made assuming that k of the data lines 14 constituting one group is “3”, but k may be “2” or an integer of “4” or more.

Further, in FIG. 9, the array of the NOT circuits Iv3, Iv2, and Iv1 starting from the transmission gate Trs is merely an example. Thus, for example, the NOT circuits Iv1, Iv2, and Iv3 may be arrayed in order starting from the transmission gate Trs. It has been described above that the electro-optical device 100 according to the embodiment is of the transmissive type, but the electro-optical device 100 may also be of a reflective type.

Next, a projection-type display device will be described as an example of an electronic apparatus to which the electro-optical device 100 according to the embodiment is applied.

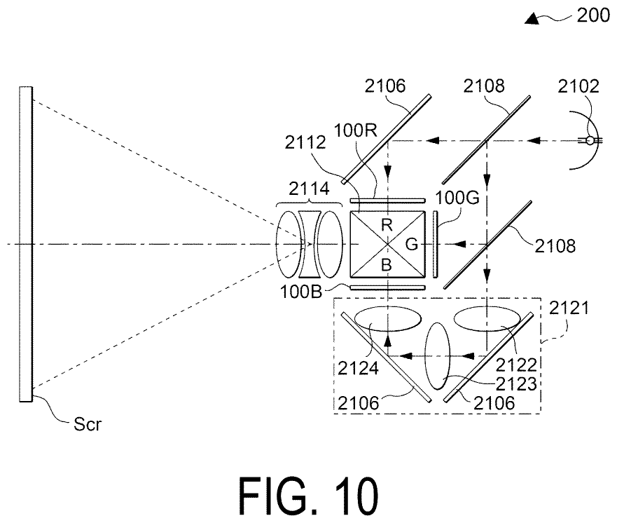

FIG. 10 is a diagram illustrating an optical configuration of a projection-type display device 200. As illustrated in the drawing, the projection-type display device 200 includes electro-optical devices 100R, 100G, and 100B.

A lamp unit 2102 constituted by a white light source such as a halogen lamp is provided inside the projection-type display device 200. Projection light emitted from the lamp unit 2102 is separated into three primary colors of red (R), green (G), and blue (B) by three mirrors 2106 and two dichroic mirrors 2108 disposed inside the projection-type display device 200. Of the light of the primary colors, light of R is incident on the electro-optical device 100R, light of G is incident on the electro-optical device 100G, and light of B is incident on the electro-optical device 100B, respectively.

Note that, since an optical path of B is longer than optical paths of R and G, it is necessary to prevent loss in the optical path of B. To this end, a relay lens system 2121 constituted by an entrance lens 2122, a relay lens 2123, and an emission lens 2124 is provided in the optical path of B.

The electro-optical devices 100R, 100G, and 100B are of the same type as the electro-optical device 100 according to the embodiment. However, as the electro-optical devices 100R, 100G, and 100B have different colors of the incident light, they are distinguished by reference signs for convenience.

A liquid crystal element of the liquid crystal panel 100R is driven based on a data signal corresponding to R supplied from a host device, and has a transmittance corresponding to the voltage of the data signal.

Therefore, in the electro-optical device 100R, a transmitted image of R is generated with the transmittance of the liquid crystal element individually controlled. Similarly, in the electro-optical device 100G, a transmitted image of G is generated based on a data signal corresponding to G, and in the electro-optical device 100B, a transmitted image of B is generated based on a data signal corresponding to B.

The transmitted images of the respective colors respectively formed by the electro-optical devices 100R, 100G, and 100B are incident on a dichroic prism 2112 from three directions. In the dichroic prism 2112, the light of R and B is refracted at 90 degrees, while the light of G travels straight. Therefore, the dichroic prism 2112 combines the images of the respective colors. The image combined by the dichroic prism 2112 enters a projection lens 2114. The projection lens 2114 enlarges and projects the combined image onto a screen Scr.

The transmitted images formed by the electro-optical devices 100R and 100B are projected after being reflected by the dichroic prism 2112, whereas the transmitted image formed by the electro-optical device 100G travels straight and is projected. Therefore, the transmitted images respectively formed by the electro-optical devices 100R and 100B each have a left-right inverted relationship with the transmitted image formed by the electro-optical device 100G.

Here, although the projection-type display device 200 has been exemplified as the electronic apparatus, the present disclosure is not limited to the projection-type display device 200. For example, the present disclosure can also be applied to a display panel of a head mounted display, an electronic viewfinder in a video camera, a lens-interchangeable digital camera, or the like, a display unit of a personal digital assistant, a wristwatch, or the like.

The following aspects, for example, can be ascertained from the above-described embodiment.

An electro-optical device according to a first aspect includes data lines grouped into a set of k, k being an integer of two or more, a data signal line to which a data signal is output, the data signal corresponding to a gray scale of a pixel and corresponding to the group of each set of k, and transmission gates provided in a one-to-one correspondence with the data lines. An input end of the transmission gate is coupled to the data signal line, an output end of the transmission gate is coupled to the data line, and a conductive state between the input end and the output end is defined based on a positive logic selection signal and a negative logic selection signal. The transmission gate includes a first transistor of a first conductivity type having a gate node to which the positive logic selection signal is supplied, and a second transistor of a second conductivity type having a gate node to which the negative logic selection signal is supplied. The data lines include a first data line and a second data line adjacent to the first data line in a first direction, and the transmission gates include a first transmission gate provided corresponding to the first data line and a second transmission gate provided corresponding to the second data line. When an array direction of the data lines is the first direction, the first transistor of the first transmission gate is adjacent to the second transistor of the second transmission gate in the first direction, the second transistor of the first transmission gate is adjacent to the first transistor of the second transmission gate in the first direction, and a channel length of the first transistor is different from a channel length of the second transistor.

In the electro-optical device according to the first aspect, since an element that writes the data signal supplied to the data signal line is the transmission gate, it is not only possible to perform the writing sufficiently, but also possible to suppress an occurrence of display unevenness caused by a difference in polarity. Further, by devising the array of the transistors of the transmission gates, it becomes easier to realize display at a high resolution.

In the electro-optical device according to a specific second aspect of the first aspect, the channel length of the first transistor is shorter than the channel length of the second transistor.

In the electro-optical device according to another specific third aspect of the first aspect, when an extending direction of the data line is a second direction, the first transistor and the second transistor of the first transmission gate corresponding to the first data line are disposed along the second direction, and the second transistor and the first transistor of the second transmission gate corresponding to the second data line are disposed along the second direction.

The electro-optical device according to another specific fourth aspect of the first aspect includes a first NOT circuit configured to supply the positive logic selection signal to the gate node of the first transistor. The first NOT circuit includes a third transistor of the first conductivity type and a fourth transistor of the second conductivity type, the third transistor of the first NOT circuit corresponding to the first data line is adjacent, in the first direction, to the fourth transistor of the first NOT circuit corresponding to the second data line, and the fourth transistor of the first NOT circuit corresponding to the first data line is adjacent, in the first direction, to the third transistor of the first NOT circuit corresponding to the second data line.

Note that a given transistor being adjacent to another transistor in the first direction means a part or the whole of the given transistor overlapping a part or the whole of the other transistor when viewed from the first direction.

The electro-optical device according to another specific fifth aspect of the first aspect includes a second NOT circuit configured to supply the negative logic selection signal to the gate node of the second transistor. The second NOT circuit includes a fifth transistor of the first conductivity type and a sixth transistor of the second conductivity type, the fifth transistor of the second NOT circuit corresponding to the first data line is adjacent, in the first direction, to the sixth transistor of the second NOT circuit corresponding to the second data line, and the sixth transistor of the second NOT circuit corresponding to the first data line is adjacent, in the first direction, to the fifth transistor of the second NOT circuit corresponding to the second data line.

An electronic apparatus according to a sixth aspect includes the electro-optical device according to any one of the first to fifth aspects.

What is claimed is:

1. An electro-optical device comprising:
data lines grouped into a set of k, k being an integer of two or more;
a data signal line to which a data signal is output, the data signal corresponding to a gray scale of a pixel and corresponding to the group of each set of k; and
transmission gates provided in a one-to-one correspondence with the data lines, wherein
an input end of the transmission gate is coupled to the data signal line,
an output end of the transmission gate is coupled to the data line,
a conductive state between the input end and the output end is defined based on a positive logic selection signal and a negative logic selection signal,
the transmission gate includes a first transistor of a first conductivity type having a gate node to which the positive logic selection signal is supplied, and a second transistor of a second conductivity type having a gate node to which the negative logic selection signal is supplied,
the data lines include a first data line and a second data line adjacent to the first data line in a first direction, the transmission gates include a first transmission gate provided corresponding to the first data line and a second transmission gate provided corresponding to the second data line,
when an array direction of the data lines is the first direction,
the first transistor of the first transmission gate is adjacent to the second transistor of the second transmission gate in the first direction,
the second transistor of the first transmission gate is adjacent to the first transistor of the second transmission gate in the first direction, and
a channel length of the first transistor is different from a channel length of the second transistor.

2. The electro-optical device according to claim 1, wherein
the channel length of the first transistor is shorter than the channel length of the second transistor.

3. The electro-optical device according to claim 1, wherein
when an extending direction of the data line is a second direction,
the first transistor and the second transistor of the first transmission gate corresponding to the first data line are disposed along the second direction, and
the second transistor and the first transistor of the second transmission gate corresponding to the second data line are disposed along the second direction.

4. The electro-optical device according to claim 1, comprising
a first NOT circuit configured to supply the positive logic selection signal to the gate node of the first transistor, wherein
the first NOT circuit includes a third transistor of the first conductivity type and a fourth transistor of the second conductivity type,
the third transistor of the first NOT circuit corresponding to the first data line is adjacent, in the first direction, to the fourth transistor of the first NOT circuit corresponding to the second data line, and
the fourth transistor of the first NOT circuit corresponding to the first data line is adjacent, in the first direction, to the third transistor of the first NOT circuit corresponding to the second data line.

5. The electro-optical device according to claim 1, comprising
a second NOT circuit configured to supply the negative logic selection signal to the gate node of the second transistor, wherein
the second NOT circuit includes a fifth transistor of the first conductivity type and a sixth transistor of the second conductivity type,
the fifth transistor of the second NOT circuit corresponding to the first data line is adjacent, in the first direction, to the sixth transistor of the second NOT circuit corresponding to the second data line, and
the sixth transistor of the second NOT circuit corresponding to the first data line is adjacent, in the first direction, to the fifth transistor of the second NOT circuit corresponding to the second data line.

6. An electronic apparatus comprising
the electro-optical device according to claim 1.
